(19) United States
(12) Patent Application Publication
(10) Pub. No.: US 2025/0334622 A1
(43) Pub. Date: Oct. 30, 2025

(54) METHOD AND MEASUREMENT APPLICATION DEVICE

(71) Applicant: Rohde & Schwarz GmbH & Co. KG, München (DE)

(72) Inventors: Thomas GUENTHER, Waldenburg (DE); Sven BARTHEL, Chemnitz (DE)

(21) Appl. No.: 18/650,847

(22) Filed: Apr. 30, 2024

(51) Int. Cl. G01R 29/027; G01R 23/10; G01R 29/033

(52) U.S. Cl. CPC G01R 29/0273; G01R 23/10; G01R 29/033

(57) ABSTRACT

The present disclosure provides a method for analyzing a signal, the method comprising receiving an incoming square-wave-like signal that comprises a predetermined frequency and a variable duty cycle, continuously forming the first derivative of the incoming square-wave-like signal, and determining at least one of the frequency, and the duty cycle of the received signal based on the first derivative. Further, the present disclosure provides a measurement application device.

### TECHNICAL FIELD

The disclosure relates to a method for analyzing a signal, and a respective measurement application device.

### BACKGROUND

Although applicable to any type of measurement application devices, the present disclosure will mainly be described in conjunction with oscilloscopes.

In electronic systems different methods for transmitting data may be implemented. At least some of these methods comprise transmitting a signal with a predefined frequency or period length, and a variable duty cycle, like in PWM signals. Such signals may be processed easily in the receiver by implementing a comparator that switches its output somewhere between the high, and low signal levels of the respective signal. This, however, only works reliably if no variable offset is present in the signal.

Accordingly, there is a need for improving signal processing for such signals.

### SUMMARY

The above stated problem is solved by the features of the independent claims. It is understood, that independent claims of a claim category may be formed in analogy to the dependent claims of another claim category.

Accordingly, it is provided:

A method for analyzing a signal, the method comprising receiving an incoming square-wave-like signal that comprises a predetermined frequency and a variable duty cycle, continuously forming the first derivative of the incoming square-wave-like signal, and determining at least one of the frequency, and the duty cycle of the received signal based on the first derivative.

Further, it is provided:

A measurement application device comprising an input interface configured to receive an incoming square-wave-like signal that comprises a predetermined frequency and a variable duty cycle, a derivation unit coupled to the input interface and configured to continuously form the first derivative of the incoming square-wave-like signal, and a determinator coupled to the derivation unit and configured to determine at least one of the frequency, and the duty cycle of the received signal based on the first derivative.

The present disclosure is based on the finding that analyzing signals with a variable duty cycle, like PWM signals, is especially difficult, if the respective signal comprises a variable DC offset. While, the teaching of the present disclosure may be applied to such signals with a variable DC offset, the teaching may also be applied to signals with a variable duty cycle that do not comprise a variable DC offset.

The present disclosure, therefore, provides a method and a measurement application device that may easily analyze a signal with a variable duty cycle and a variable DC offset.

To this end, the method comprises receiving an incoming square-wave-like signal that comprises a predetermined frequency and a variable duty cycle. In the measurement application device, the incoming square-wave-like signal may be acquired e.g., with a measurement interface or port of the measurement application device.

The term “square-wave-like signal” refers to the incoming square-wave-like signal comprising a cyclical signal with a rising and a falling edge in each one of the signal periods. The variable duty cycle may be implemented by moving either the raising edge or the falling edge in a period, wherein the distance between the raising edge and the falling edge in relation to the period duration defines the duty cycle. The definition of the incoming square-wave-like signal comprising a “predetermined frequency” may refer to the signal comprising a fixed or variable frequency. As indicated above, the incoming square-wave-like signal may comprise a DC offset, especially a variable DC offset, but not necessarily comprises such an offset.

The method further comprises continuously forming the first derivative of the incoming square-wave-like signal. In the measurement application device a hardware device, like a signal processor, may perform such calculations.

The first derivative will comprise a spike for each edge in the incoming square-wave-like signal. The spikes in the first derivative will be present independently of the DC offset, since they will be caused by the signal level change in the incoming square-wave-like signal that is caused by the rising and falling edges in the incoming square-wave-like signal.

The method further comprises determining at least one of the frequency, and the duty cycle of the received signal based on the first derivative. In the measurement application device, the above-mentioned hardware device may perform the respective determination.

As explained above, the first derivative will comprise spikes for each one of the rising and falling edges in the incoming square-wave-like signal. Consequently, it is possible to determine any one of the frequency, and the duty cycle based on the spikes in the first derivative. Again, any DC offset that may be present in the incoming square-wave-like signal will not have any influence in the determination of the frequency or the duty cycle, since in the first derivative such a DC offset is removed.

Summing up, with the method or the measurement application device according to the present disclosure, it possible to reliably determine the frequency and the duty cycle of an incoming signal independently of any possible constant or variable DC offset that the incoming signal may comprise.

Further embodiments of the present disclosure are subject of the further dependent claims and of the following description, referring to the drawings.

In the following, the dependent claims referring directly or indirectly to claim 1 are described in more detail. For the avoidance of doubt, the features of the dependent claims relating to independent claim 1 can be combined in all variations with each other and the disclosure of the description is not limited to the claim dependencies as specified in the claim set. Further, the features of the dependent claims referring to independent claim 1 may be combined with any of the features of the other independent claims or the dependent claims relating to any one of the other independent claims. In a respective method, respective method steps may perform the function of the respective apparatus elements, and in a respective apparatus, respective apparatus elements may perform the respective method steps.

In an embodiment, which can be combined with all other embodiments mentioned above or below, continuously forming the first derivative may comprise inputting the incoming square-wave-like signal to a differentiating circuit, e.g., an RC circuit or a high-pass filter circuit.

Using a differentiating circuit allows to provide the first derivative with a passive circuit that may easily be implemented without requiring any processing unit that needs to be programmed to perform all required calculations.

With such a differentiating circuit, the calculation of the first derivative may be offloaded and the method may easily be implemented, and the complexity of a firmware or application program of the measurement application device may be reduced.

In a further embodiment, which can be combined with all other embodiments mentioned above or below, continuously forming the first derivative may comprise converting the incoming square-wave-like signal into a time-discrete digital signal, and determining the first derivative based on the time-discrete digital signal.

Instead of using a differentiating circuit, the first derivative may also be calculated in the digital domain. To this end, the incoming square-wave-like signal may be converted into a time-discrete digital signal. For example, a respective analog-to-digital converter may be provided e.g., on the measurement application device.

Any possible algorithm or calculation that allows determining the first derivative for the time-discrete digital signal may be used. The first derivative for the time-discrete digital signal may e.g., be determined by continuously calculating the difference between a current sample of the time-discrete digital signal, and the previous sample of the time-discrete digital signal. In embodiments, multiple samples may be averaged. For example, an average may be generated for up to a maximum number of samples, if the single samples do not differ from each other more than a predetermined threshold. As soon as one of the samples differs from the other samples more than the predetermined threshold, a first value may be determined, and a further value for calculating the first derivative may be determined based on the following samples.

As explained above, this just an exemplary way of calculating the first derivative, and any other algorithm may be used.

In another embodiment, which can be combined with all other embodiments mentioned above or below, the time-discrete digital signal may comprise a sample rate that is at least two times the frequency resulting from the shortest possible duty cycle interval of the incoming square-wave-like signal.

In order to fully detect every single edge of the incoming square-wave-like signal, it is necessary to acquire samples of the incoming square-wave-like signal at least once in the low phase, and the high phase of a period of the incoming square-wave-like signal.

Consequently, the minimum sample rate should be set to a sample rate that results from the shortest possible high phase or low phase. The duration of the shortest possible high phase or low phase is defined by the shortest possible duty cycle. If for example, in a 1 kHz signal, the shortest possible duty cycle is 1%, the duration of the high phase of the respective signal period will be 1% of 1/1 kHz (1 ms), wherein 1% of Ims equals 10 μs (100 kHz). In embodiments, the sample rate may be 100 kHz in such examples i.e., the frequence resulting from the duration of the high phase or low phase. The sample rate of the time-discrete digital signal should consequently be at least 200 kHz.

In an embodiment, which can be combined with all other embodiments mentioned above or below, determining the frequency of the received incoming square-wave-like signal may comprise dividing one through the duration between a positive spike in the first derivative and the previous or next positive spike in the first derivative, or dividing one through the duration between a negative spike in the first derivative and the previous or next negative spike in the first derivative.

A signal with a variable duty cycle usually has either a variable falling edge position in each period between two static raising edges, or a variable raising edge position in each period between two static falling edges.

The distance or time duration between the two static edges in each period of the incoming square-wave-like signal determines the frequency of the signal.

By determining the frequency, and, therefore, also the period or period duration of the incoming square-wave-like signal, it is possible to calculate the duty cycle not only for signals with a variable DC offset, but also for signals with a variable or unknown frequency.

In the first derivative, a raising edge in the incoming square-wave-like signal will cause a positive spike, while a falling edge in the incoming square-wave-like signal will cause a negative spike.

The positive spikes and negative spikes may be identified in the first derivative by determining maxima and minima in the first derivative. The identified positions may be used to determine the position of the respective edge in the incoming square-wave-like signal.

Based on the polarity of the maxima and minima, the slope direction of the respective edge i.e., a raising edge or falling edge, may be determined. While a maximum will usually comprise a positive polarity and refer to a raising edge, and a minimum will usually comprise a negative polarity and refer to a falling edge, the logic representation may be different. For this reason, in embodiments, the polarity may be determined independently.

In another embodiment, which can be combined with all other embodiments mentioned above or below, determining the duty cycle of the received incoming square-wave-like signal may comprise dividing the duration between a positive spike in the first derivative and the previous or next negative spike in the first derivative through the duration between the positive spike in the first derivative and the previous or next positive spike in the first derivative, or dividing the duration between a negative spike in the first derivative and the previous or next positive spike in the first derivative through the duration between the negative spike in the first derivative and the previous or next negative spike in the first derivative.

In the incoming square-wave-like signal the falling edge may be the moving edge that determines the duty cycle between two raising edges. With such an incoming square-wave-like signal, the total duration of a period may be determined by the duration between two positive spikes in the first derivative. The duty cycle may be determined based on this total duration of a period, and the duration between the respective positive spike, and the next or previous negative spike, which characterizes a respective falling edge.

In contrast, in the incoming square-wave-like signal the raising edge may be the moving edge that determines the duty cycle between two falling edges. With such an incoming square-wave-like signal, the total duration of a period may be determined by the duration between two negative spikes in the first derivative. The duty cycle may be determined based on this total duration of a period, and the duration between the respective negative spike, and the next or previous positive spike, which characterizes a respective raising edge.

In embodiments, the fixed duration that characterizes a period of the incoming square-wave-like signal may be determined during every period, or may be determined only once, or may be predefined without the need to continuously determine this duration.

In a further embodiment, which can be combined with all other embodiments mentioned above or below, the incoming square-wave-like signal may comprise at least in part a time-modulated signal.

A time-modulated signal in the context of the present disclosure refers to any signal that comprises a time-dependent shape. Such a signal may e.g., comprise a PWM-signal with or without a constant or variable DC offset.

In an embodiment, which can be combined with all other embodiments mentioned above or below, the incoming square-wave-like signal may comprise two signal stages, or more than two signal stages.

A signal with two signal states in the context of the present disclosure is any type of signal that has two characterizing signal levels or stages, like a binary signal that has signal stages 0 and 1, which may be characterized by respective voltage of current levels.

Multi-level signals with more than two characterizing signal levels, like 3 or more signal levels are also possible. In such signals, the respective signal stage or level may indicate additional data or information in addition to the duty cycle. For example, in a multi-level signal, a PWM-signal with two relevant signal stages may be overlaid with two different DC offset signal levels. The two DC offset signal levels may each characterize some kind of additional information for the receiver of the incoming square-wave-like signal. The DC offset signal levels may be chosen such that for one DC offset signal level the low signal level of the PWM-signal may be equal to the high signal level of the PWM-signal in the other DC offset signal level. In other embodiments, the DC offset signal levels may be chosen such that for one DC offset signal level the signal levels of the PWM-signal are both different than for the other DC offset signal level.

In another embodiment, which can be combined with all other embodiments mentioned above or below, the incoming square-wave-like signal may comprise a variable offset.

As indicated above, the teaching of the present disclosure may be used with incoming square-wave-like signal that comprise no offset, or a fixed offset, or even a variable offset.

In an embodiment, which can be combined with all other embodiments mentioned above or below, the method may further comprise generating the incoming square-wave-like signal based on a set of predefined signal parameters, and outputting the generated incoming square-wave-like signal.

In embodiments, the incoming square-wave-like signal may not be a signal received form e.g., a device under test. Instead, in embodiments, the incoming square-wave-like signal may be generated e.g., in a respective method step or by a respective signal generator in the measurement application device.

Such a signal may e.g., be generated for outputting the signal to a device under test for providing a test signal to the device under test.

In an embodiment, which can be combined with all other embodiments mentioned above or below, the method may further comprise gating a signal measurement or signal analysis based on the determined frequency or duty cycle.

In measurement application devices measurement functions and/or signal analysis may be gated, also called triggered, by specific events. The method may, therefore, comprise gating a signal measurement or signal analysis based on the determined frequency or duty cycle.

For example, a gate trigger or trigger may be determined that gates or triggers a signal measurement or signal analysis if a specific duty cycle is present, or is not present, or if the measured duty cycle is higher or lower than a threshold. The same criteria may be applied to the determined frequency.

### BRIEF DESCRIPTION OF THE DRAWINGS

For a more complete understanding of the present disclosure and advantages thereof, reference is now made to the following description taken in conjunction with the accompanying drawings. The disclosure is explained in more detail below using exemplary embodiments which are specified in the schematic figures of the drawings, in which:

FIG. 1 shows a flow diagram of an embodiment of a method according to the present disclosure;

FIG. 2 shows a flow diagram of another embodiment of a method according to the present disclosure;

FIG. 3 shows a flow diagram of a further embodiment of a method according to the present disclosure;

FIG. 4 shows a flow diagram of another further embodiment of a method according to the present disclosure;

FIG. 5 shows a flow diagram of another embodiment of a method according to the present disclosure;

FIG. 6 shows a block diagram of an embodiment of a measurement application device according to the present disclosure;

FIG. 7 shows a block diagram of another embodiment of a measurement application device according to the present disclosure;

FIG. 8 shows a block diagram of a further embodiment of a measurement application device according to the present disclosure;

FIG. 9 shows a diagram with an incoming square-wave-like signal, and a corresponding first derivative according to the present disclosure; and

FIG. 10 shows a diagram with a zoomed-in incoming square-wave-like signal, and a corresponding first derivative according to the present disclosure.

In the figures like reference signs denote like elements unless stated otherwise.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

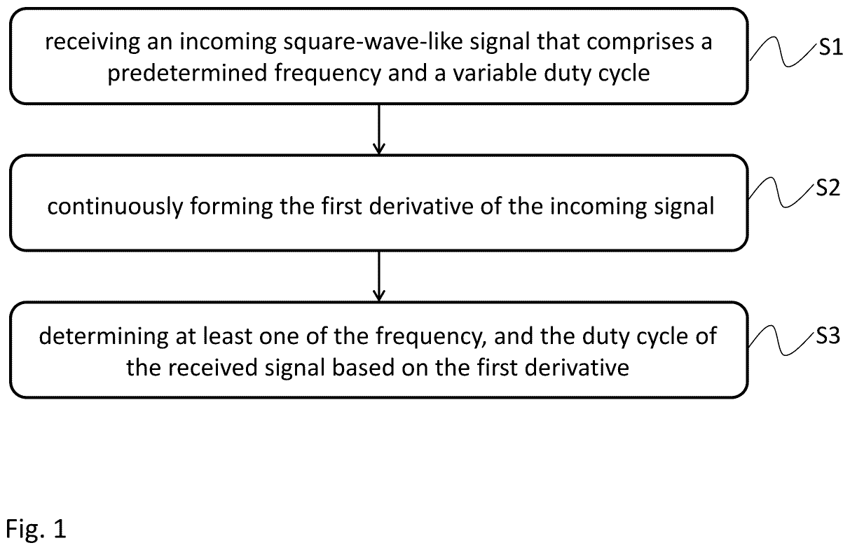

FIG. 1 shows a flow diagram of a method for analyzing a signal.

The method comprises receiving S1 an incoming square-wave-like signal that comprises a predetermined frequency and a variable duty cycle, continuously forming S2 the first derivative of the incoming square-wave-like signal, and determining S3 at least one of the frequency, and the duty cycle of the received signal based on the first derivative.

The incoming square-wave-like signal may comprise at least in part a time-modulated signal, like a PWM signal. Further, the incoming square-wave-like signal may comprise two representative signal stages or levels, more than two signal stages or levels. The incoming square-wave-like signal may comprise a variable offset.

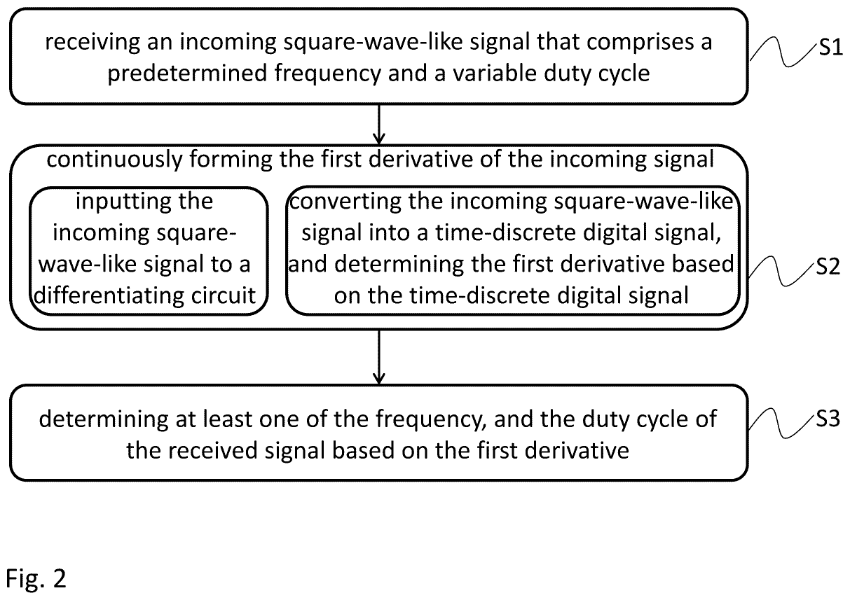

FIG. 2 shows a flow diagram of a method for analyzing a signal that is based on the method of FIG. 1. Consequently, the method comprises receiving S1 an incoming square-wave-like signal that comprises a predetermined frequency and a variable duty cycle, continuously forming S2 the first derivative of the incoming square-wave-like signal, and determining S3 at least one of the frequency, and the duty cycle of the received signal based on the first derivative.

The step S2 of continuously forming the first derivative of the incoming square-wave-like signal comprises two alternative possibilities of forming the first derivative. The two alternatives may, in embodiments, also be performed in parallel.

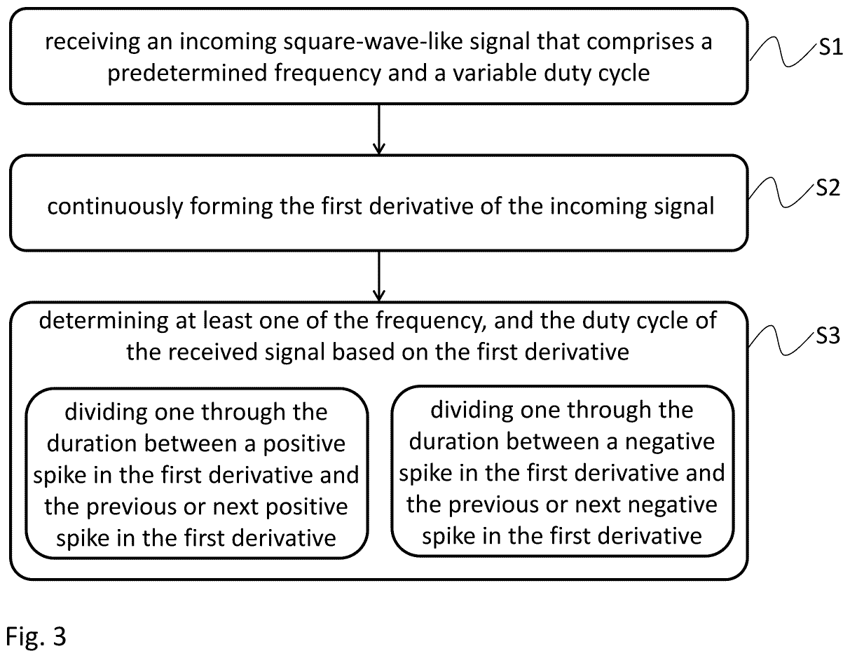

FIG. 3 shows a flow diagram of a method for analyzing a signal that is based on the method of FIG. 1. Consequently, the method comprises receiving S1 an incoming square-wave-like signal that comprises a predetermined frequency and a variable duty cycle, continuously forming S2 the first derivative of the incoming square-wave-like signal, and determining S3 at least one of the frequency, and the duty cycle of the received signal based on the first derivative.

The step S3 of determining at least one of the frequency, and the duty cycle of the received signal based on the first derivative comprises two alternatives for determining the frequency of the incoming square-wave-like signal.

The first alternative comprises dividing one through the duration between a positive spike in the first derivative and the previous or next positive spike in the first derivative.

The second alternative comprises dividing one through the duration between a negative spike in the first derivative and the previous or next negative spike in the first derivative.

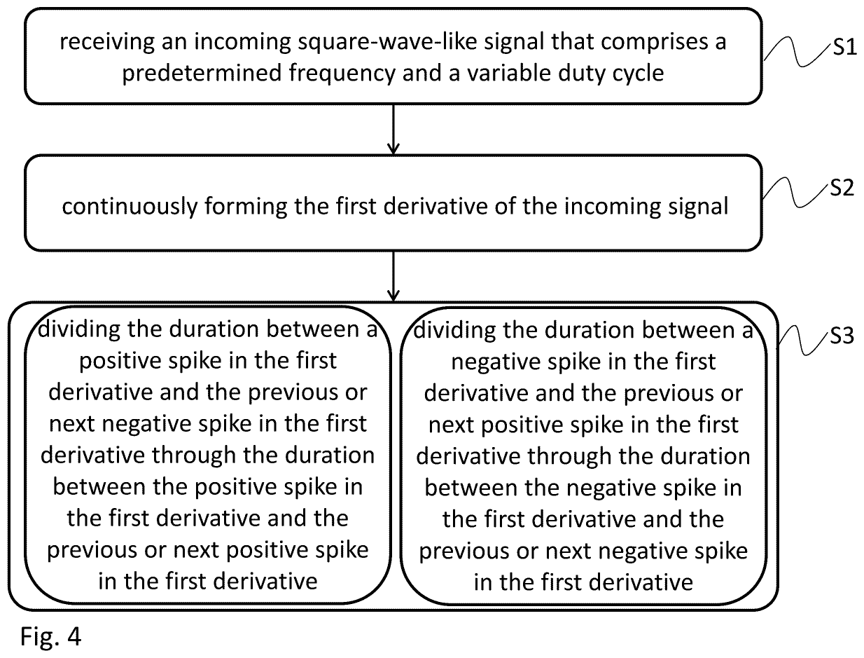

FIG. 4 shows a flow diagram of a method for analyzing a signal that is based on the method of FIG. 1. Consequently, the method comprises receiving S1 an incoming square-wave-like signal that comprises a predetermined frequency and a variable duty cycle, continuously forming S2 the first derivative of the incoming square-wave-like signal, and determining S3 at least one of the frequency, and the duty cycle of the received signal based on the first derivative.

The step S3 of determining at least one of the frequency, and the duty cycle of the received signal based on the first derivative comprises two alternatives for determining the duty cycle of the incoming square-wave-like signal.

The first alternative, comprises dividing the duration between a positive spike in the first derivative and the previous or next negative spike in the first derivative through the duration between the positive spike in the first derivative and the previous or next positive spike in the first derivative.

The second alternative comprises dividing the duration between a negative spike in the first derivative and the previous or next positive spike in the first derivative through the duration between the negative spike in the first derivative and the previous or next negative spike in the first derivative.

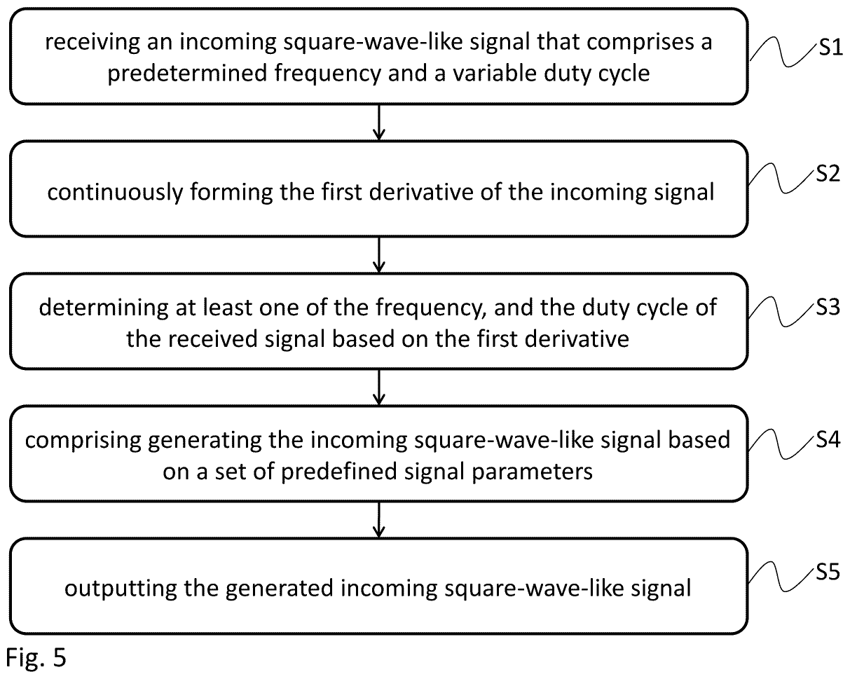

FIG. 5 shows a flow diagram of a method for analyzing a signal that is based on the method of FIG. 1. Consequently, the method comprises receiving S1 an incoming square-wave-like signal that comprises a predetermined frequency and a variable duty cycle, continuously forming S2 the first derivative of the incoming square-wave-like signal, and determining S3 at least one of the frequency, and the duty cycle of the received signal based on the first derivative.

The method of FIG. 5 further comprises generating S4 the incoming square-wave-like signal based on a set of predefined signal parameters, and outputting S5 the generated incoming square-wave-like signal.

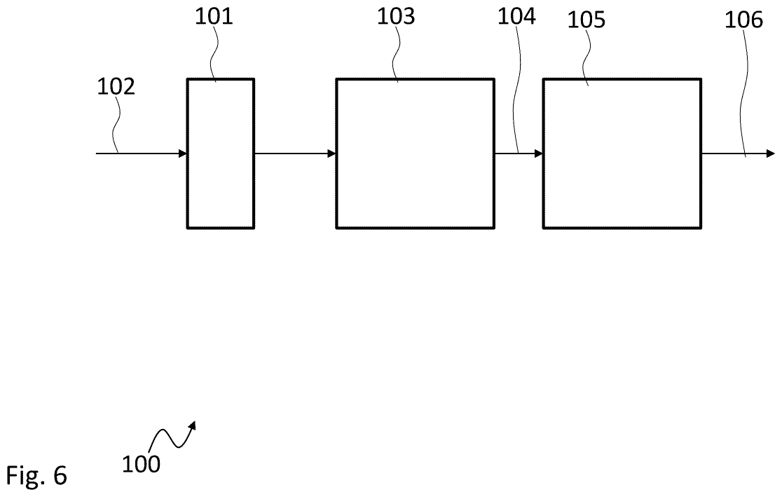

FIG. 6 shows a block diagram of a measurement application device 100. The measurement application device 100 comprises an input interface 101 that receives an incoming square-wave-like signal 102 that comprises a predetermined frequency and a variable duty cycle.

Further, the measurement application device 100 comprises a derivation unit 103 coupled to the input interface 101 that continuously forms the first derivative 104 of the incoming square-wave-like signal 102. The measurement application device 100 further comprises a determinator 105 coupled to the derivation unit 103 that determines and outputs a signal 106 that comprises at least one of the frequency, and the duty cycle of the received signal based on the first derivative 104.

The derivation unit 103 may comprise a differentiating circuit. In addition, or as alternative, the derivation unit 103 may comprise an analog-to-digital converter configured to convert the incoming square-wave-like signal 102 into a time-discrete digital signal, and a processing element configured to continuously calculate the difference between a current sample of the time-discrete digital signal, and the previous sample of the time-discrete digital signal.

The analog-to-digital converter may comprise a sample rate that is at least two times the frequency resulting from the shortest possible duty cycle interval of the incoming square-wave-like signal 102.

The determinator 105 may comprise a processing element configured to determine the frequency of the received incoming square-wave-like signal 102 by dividing one through the duration between a positive spike in the first derivative 104 and the previous or next positive spike in the first derivative 104, or dividing one through the duration between a negative spike in the first derivative 104 and the previous or next negative spike in the first derivative 104.

The determinator 105 may also comprise a processing element configured to determine the duty cycle of the received incoming square-wave-like signal 102 by dividing the duration between a positive spike in the first derivative 104 and the previous or next negative spike in the first derivative 104 through the duration between the positive spike in the first derivative 104 and the previous or next negative spike in the first derivative 104, or dividing the duration between a negative spike in the first derivative 104 and the previous or next positive spike in the first derivative 104 through the duration between the negative spike in the first derivative 104 and the previous or next negative spike in the first derivative 104.

In embodiments, the measurement application device 100 further comprises a signal generator configured to generate the incoming square-wave-like signal 102 based on a set of predefined signal parameters, and output the generated incoming square-wave-like signal 102.

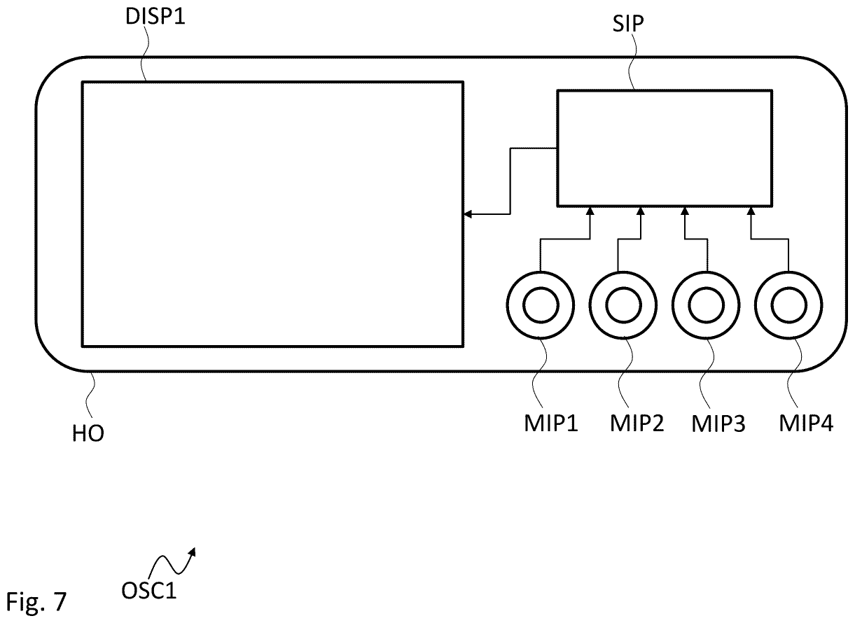

FIG. 7 shows a block diagram of an oscilloscope OSCI that may be used as an embodiment of a measurement application device according to the present disclosure.

The oscilloscope OSCI comprises a housing HO that accommodates four measurement inputs MIP1, MIP2, MIP3, MIP4 that are coupled to a signal processor SIP for processing any measured signals. The signal processor SIP is coupled to a display DISPI for displaying the measured signals to a user.

Although not explicitly shown, it is understood, that the oscilloscope OSCI may also comprise signal outputs. Such signal outputs may for example serve to output calibration signals. Such calibration signals allow calibrating the measurement setup prior to performing any measurement. The process of calibrating and correcting any measurement signals based on the calibration may also be called de-embedding and may comprise applying respective algorithms on the measured signals.

In the oscilloscope OSCI the measurement inputs MIP1, MIP2, MIP3, MIP4 may be used as the input interface, and the signal processor SIP or an additional processing element may perform all calculation functions of the method according to the present disclosure, or may implement the calculation functions. Of course, a communication interface may be provided in the oscilloscope OSCI for communication with other measurement application devices.

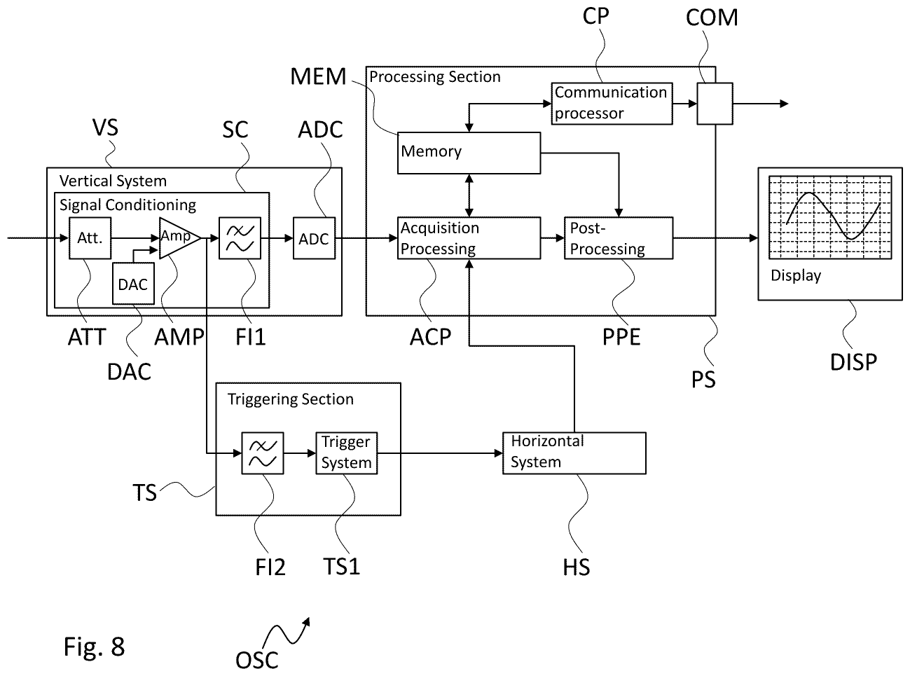

FIG. 8 shows a block diagram of an oscilloscope OSC that may be an implementation of a measurement application device according to the present disclosure. The oscilloscope OSC is implemented as a digital oscilloscope. However, the present disclosure may also be implemented with any other type of oscilloscope.

The oscilloscope OSC exemplarily comprises five general sections, the vertical system VS, the triggering section TS, the horizontal system HS, the processing section PS and the display DISP. It is understood, that the partitioning into five general sections is a logical partitioning and does not limit the placement and implementation of any of the elements of the oscilloscope OSC in any way.

The vertical system VS mainly serves for offsetting, attenuating and amplifying a signal to be acquired. The signal may for example be modified to fit in the available space on the display DISP or to comprise a vertical size as configured by a user.

To this end, the vertical system VS comprises a signal conditioning section SC with an attenuator ATT and a digital-to-analog-converter DAC that are coupled to an amplifier AMP. The amplifier AMP is coupled to a filter FII, which in the shown example is provided as a low pass filter. The vertical system VS also comprises an analog-to-digital converter ADC that receives the output from the filter FII and converts the received analog signal into a digital signal.

The attenuator ATT and the amplifier AMP serve to scale the amplitude of the signal to be acquired to match the operation range of the analog-to-digital converter ADC. The digital-to-analog-converter DAC serves to modify the DC component of the input signal to be acquired to match the operation range of the analog-to-digital converter ADC. The filter FIl serves to filter out unwanted high frequency components of the signal to be acquired.

The triggering section TS operates on the signal as provided by the amplifier AMP. The triggering section TS comprises a filter FI2, which in this embodiment is implemented as a low pass filter. The filter FI2 is coupled to a trigger system TS1.

The triggering section TS serves to capture predefined signal events and allows the horizontal system HS to e.g., display a stable view of a repeating waveform, or to simply display waveform sections that comprise the respective signal event. It is understood, that the predefined signal event may be configured by a user via a user input of the oscilloscope OSC.

Possible predefined signal events may for example include, but are not limited to, when the signal crosses a predefined trigger threshold in a predefined direction i.e., with a rising or falling slope. Such a trigger condition is also called an edge trigger. Another trigger condition is called “glitch triggering” and triggers, when a pulse occurs in the signal to be acquired that has a width that is greater than or less than a predefined amount of time.

In order to allow an exact matching of the trigger event and the waveform that is shown on the display DISP, a common time base may be provided for the analog-to-digital converter ADC and the trigger system TS1.

It is understood, that although not explicitly shown, the trigger system TS1 may comprise at least one of configurable voltage comparators for setting the trigger threshold voltage, fixed voltage sources for setting the required slope, respective logic gates like c.g., a XOR gate, and FlipFlops to generate the triggering signal.

The triggering section TS is exemplarily provided as an analog trigger section. It is understood, that the oscilloscope OSC may also be provided with a digital triggering section. Such a digital triggering section will not operate on the analog signal as provided by the amplifier AMP but will operate on the digital signal as provided by the analog-to-digital converter ADC.

A digital triggering section may comprise a processing element, like a processor, a DSP, a CPLD, an ASIC or an FPGA to implement digital algorithms that detect a valid trigger event.

The horizontal system HS is coupled to the output of the trigger system TS1 and mainly serves to position and scale the signal to be acquired horizontally on the display DISP.

The oscilloscope OSC further comprises a processing section PS that implements digital signal processing and data storage for the oscilloscope OSC. The processing section PS comprises an acquisition processing clement ACP that is couple to the output of the analog-to-digital converter ADC and the output of the horizontal system HS as well as to a memory MEM and a post processing element PPE.

The acquisition processing element ACP manages the acquisition of digital data from the analog-to-digital converter ADC and the storage of the data in the memory MEM. The acquisition processing element ACP may for example comprise a processing element with a digital interface to the analog-to-digital converter ADC2 and a digital interface to the memory MEM. The processing element may for example comprise a microcontroller, a DSP, a CPLD, an ASIC or an FPGA with respective interfaces. In a microcontroller or DSP, the functionality of the acquisition processing element ACP may be implemented as computer readable instructions that are executed by a CPU. In a CPLD or FPGA the functionality of the acquisition processing element ACP may be configured in to the CPLD or FPGA opposed to software being executed by a processor.

The processing section PS further comprises a communication processor CP and a communication interface COM.

The communication processor CP may be a device that manages data transfer to and from the oscilloscope OSC. The communication interface COM for any adequate communication standard like for example, Ethernet, WIFI, Bluetooth, NFC, an infra-red communication standard, and a visible-light communication standard.

The communication processor CP is coupled to the memory MEM and may use the memory MEM to store and retrieve data.

Of course, the communication processor CP may also be coupled to any other element of the oscilloscope OSC to retrieve device data or to provide device data that is received from the management server.

The post processing element PPE may be controlled by the acquisition processing element ACP and may access the memory MEM to retrieve data that is to be displayed on the display DISP. The post processing element PPE may condition the data stored in the memory MEM such that the display DISP may show the data e.g., as waveform to a user. The post processing element PPE may also realize analysis functions like cursors, waveform measurements, histograms, or math functions.

The display DISP controls all aspects of signal representation to a user, although not explicitly shown, may comprise any component that is required to receive data to be displayed and control a display device to display the data as required.

It is understood, that even if it is not shown, the oscilloscope OSC may also comprise a user interface for a user to interact with the oscilloscope OSC. Such a user interface may comprise dedicated input elements like for example knobs and switches. At least in part the user interface may also be provided as a touch sensitive display device.

In the oscilloscope OSC, any one of the processing elements in the processing section PS or an additional processing element may perform all calculation functions of the method according to the present disclosure, or may implement the calculation functions.

It is understood, that all elements of the oscilloscope OSC that perform digital data processing may be provided as dedicated elements. As alternative, at least some of the above-described functions may be implemented in a single hardware element, like for example a microcontroller, DSP, CPLD or FPGA. Generally, the above-describe logical functions may be implemented in any adequate hardware element of the oscilloscope OSC and not necessarily need to be partitioned into the different sections explained above.

Although not shown in FIGS. 7, and 8, the oscilloscopes of FIGS. 7, and 8 may each comprise a signal generator and a respective output port for generating the incoming square-wave-like signal.

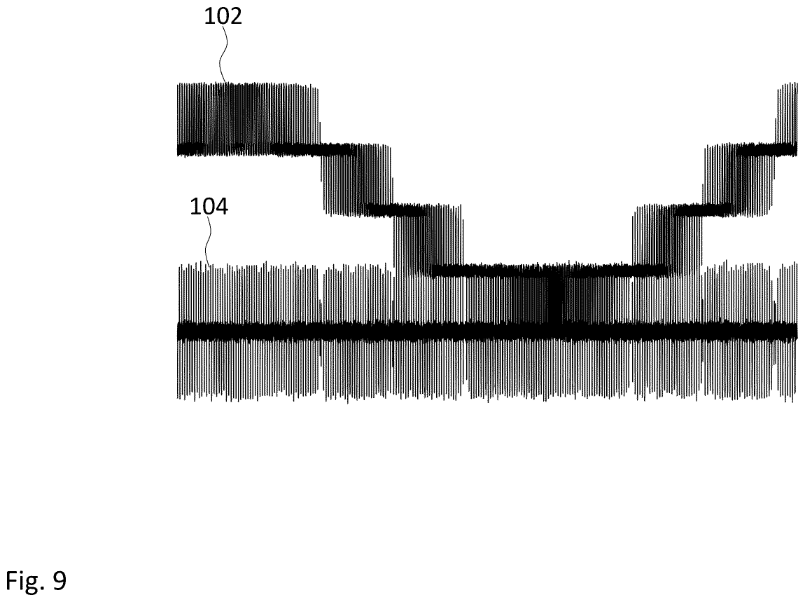

FIG. 9 shows a diagram with an incoming square-wave-like signal 102, and a corresponding first derivative 104.

The incoming square-wave-like signal 102, a PWM signal, comprises a variable DC offset, wherein the DC offset has four different levels, as can be seen in the diagram of FIG. 9.

It can also be seen that the first derivative 104 has a constant zero-level offset without any offset being applied independently of the DC offset being applied to the incoming square-wave-like signal 102. The first derivative 104 may have signal levels that deviate from the usual spikes where the incoming square-wave-like signal 102 has a DC offset change.

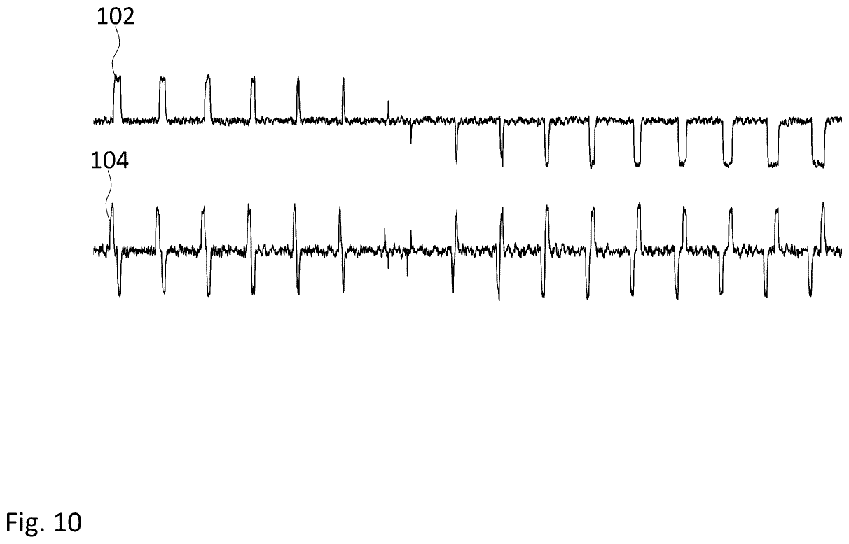

FIG. 10 shows a diagram with a zoomed-in incoming square-wave-like signal 102, and a corresponding first derivative 104.

In the diagram of FIG. 10, it can be seen that the distance between a positive spike, and a consecutive negative spike of the first derivative 104 is as large as the distance between a rising edge and the consecutive falling edge of the incoming square-wave-like signal 102.

Consequently, the distance between a maximum, and a consecutive minimum of the first derivative 104 in relation to the distance between two consecutive maxima of the first derivative 104 may be used to calculate the duty cycle of the incoming square-wave-like signal 102.

The processes, methods, or algorithms disclosed herein can be deliverable to/implemented by a processing device, controller, or computer, which can include any existing programmable electronic control unit or dedicated electronic control unit. Similarly, the processes, methods, or algorithms can be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, case of assembly, etc. As such, to the extent any embodiments are described as less desirable than other embodiments or prior art implementations with respect to one or more characteristics, these embodiments are not outside the scope of the disclosure and can be desirable for particular applications.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

The abstract of the disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

### LIST OF REFERENCE SIGNS

100 measurement application device
101 input interface
102 incoming square-wave-like signal
103 derivation unit
104 first derivative
105 determinator
106 output signal
OSC1 oscilloscope
HO housing
MIP1, MIP2, MIP3, MIP4 measurement input
SIP signal processing
DISP1 display
OSC oscilloscope
VS vertical system
SC signal conditioning
ATT attenuator
DAC1 analog-to-digital converter
AMP amplifier
FI1 filter
DAC digital-to-analog converter
ADC analog-to-digital converter
TS triggering section
AMP2 amplifier
FI2 filter
TS1 trigger system
HS horizontal system
PS processing section
ACP acquisition processing clement
MEM memory
PPE post processing element
DISP display

What is claimed is:

1. A method for analyzing a signal, the method comprising:
receiving an incoming square-wave-like signal that comprises a predetermined frequency and a variable duty cycle;
continuously forming the first derivative of the incoming square-wave-like signal; and
determining at least one of the frequency, and the duty cycle of the received signal based on the first derivative.

2. The method according to claim 1, wherein continuously forming the first derivative comprises inputting the incoming square-wave-like signal to a differentiating circuit.

3. The method according to claim 1, wherein continuously forming the first derivative comprises converting the incoming square-wave-like signal into a time-discrete digital signal, and determining the first derivative based on the time-discrete digital signal.

4. The method according to claim 3, wherein the time-discrete digital signal comprises a sample rate that is at least two times the frequency resulting from the shortest possible duty cycle interval of the incoming square-wave-like signal.

5. The method according to claim 1, wherein determining the frequency of the received incoming square-wave-like signal comprises:
dividing one through the duration between a positive spike in the first derivative and the previous or next positive spike in the first derivative; or
dividing one through the duration between a negative spike in the first derivative and the previous or next negative spike in the first derivative.

6. The method according to claim 1, wherein determining the duty cycle of the received incoming square-wave-like signal comprises:
dividing the duration between a positive spike in the first derivative and the previous or next negative spike in the first derivative through the duration between the positive spike in the first derivative and the previous or next positive spike in the first derivative; or
dividing the duration between a negative spike in the first derivative and the previous or next positive spike in the first derivative through the duration between the negative spike in the first derivative and the previous or next negative spike in the first derivative.

7. The method according to claim 1, wherein the incoming square-wave-like signal comprises at least in part a time-modulated signal.

8. The method according to claim 1, wherein the incoming square-wave-like signal comprises:
two signal stages; or
more than two signal stages.

9. The method according to claim 1, wherein the incoming square-wave-like signal comprises a variable offset.

10. The method according to claim 1, further comprising generating the incoming square-wave-like signal based on a set of predefined signal parameters; and
outputting the generated incoming square-wave-like signal.

11. A measurement application device comprising:
an input interface configured to receive an incoming square-wave-like signal that comprises a predetermined frequency and a variable duty cycle;
a derivation unit coupled to the input interface and configured to continuously form the first derivative of the incoming square-wave-like signal; and
a determinator coupled to the derivation unit and configured to determine at least one of the frequency, and the duty cycle of the received signal based on the first derivative.

12. The measurement application device according to claim 11, wherein the derivation unit comprises a differentiating circuit.

13. The measurement application device according to claim 11, wherein the derivation unit comprises:
an analog-to-digital converter configured to convert the incoming square-wave-like signal into a time-discrete digital signal; and
a processing element configured to continuously calculate the difference between a current sample of the time-discrete digital signal, and the previous sample of the time-discrete digital signal.

14. The measurement application device according to claim 13, wherein the analog-to-digital converter comprises a sample rate that is at least two times the frequency resulting from the shortest possible duty cycle interval of the incoming square-wave-like signal.

15. The measurement application device according to claim 11, wherein the determinator comprises a processing element configured to determine the frequency of the received incoming square-wave-like signal by:
dividing one through the duration between a positive spike in the first derivative and the previous or next positive spike in the first derivative; or
dividing one through the duration between a negative spike in the first derivative and the previous or next negative spike in the first derivative.

16. The measurement application device according to claim 11, wherein the determinator comprises a processing element configured to determine the duty cycle of the received incoming square-wave-like signal by:
dividing the duration between a positive spike in the first derivative and the previous or next negative spike in the first derivative through the duration between the positive spike in the first derivative and the previous or next negative spike in the first derivative; or
dividing the duration between a negative spike in the first derivative and the previous or next positive spike in the first derivative through the duration between the negative spike in the first derivative and the previous or next negative spike in the first derivative.

17. The measurement application device according to claim 11, wherein the incoming square-wave-like signal comprises at least in part a time-modulated signal.

18. The measurement application device according to claim 11, wherein the incoming square-wave-like signal comprises:
two signal stages; or
more than two signal stages.

19. The measurement application device according to claim 11, wherein the incoming square-wave-like signal comprises a variable offset.

20. The measurement application device according to claim 11, further comprising a signal generator configured to generate the incoming square-wave-like signal based on a set of predefined signal parameters, and output the generated incoming square-wave-like signal.
